(19) United States
(12) Patent Application Publication
(10) Pub. No.: US 2025/0087467 A1
(43) Pub. Date: Mar. 13, 2025

(54) SHALLOW ETCHING PROCESS CHAMBER

(71) Applicant: VM Inc., Icheon-si (KR)

(72) Inventors: Sang Woo LEE, Suwon-si (KR); Woo Hyung CHOI, Seongnam-si (KR)

(21) Appl. No.: 18/782,435

(22) Filed: Jul. 24, 2024

(30) Foreign Application Priority Data
Sep. 12, 2023 (KR) 10-2023-0121068

(51) Int. Cl. H01J 37/32; H01L 21/67

(52) U.S. Cl. CPC H01J 37/32715; H01J 37/3244; H01J 37/32357; H01J 2237/2007; H01J 2237/20235; H01J 2237/334; H01L 21/67069

(57) ABSTRACT

A shallow process chamber comprises: a susceptor disposed within a chamber volume 11; a lifting ring 13 formed at the susceptor, and a moving means for moving the lift ring 13 up and down, wherein a wafer W moves up and down above an electrostatic chuck 12 by moving the lift ring 13 up and down.

### BACKGROUND OF THE INVENTION

### Field of the Invention

The present invention relates to a shallow etching process chamber, in particular a shallow etching process chamber capable of adjusting an etching process volume in course of an etching process.

### Description of the Related Art

As the semiconductor pattern becomes refined and stacked in a 3D structure, a technology to remove a thin oxidized film or to remove a thin film in a very high aspect ratio has being required in some etching processes. And also, technologies for etching slowly and repeatedly without a loading effect in an atomic layer level have being developed in order to minimize the loading effect corresponding to an etching amount difference between a relatively wide pattern and a relatively narrow pattern. An atomic layer etching technology (ALE), an atomic layer removing technology (ALR) or a dry cleaning technology for the very high aspect ratio atomic layer etching technology is in the process of development. Such a shallow etching process comprises a modification step by a self-limited modification reaction at a low temperature of 80° C. or lower and a removing step for removing a thin film of an atomic level modified at a high temperature of 120° C. or higher as a common aspect. A known equipment for the shallow etching may perform both of the modification step and the removal step through a thermal process, and therefore, the known equipment has a disadvantage that much time required for the process limits its productivity. And an equipment for performing the modification step using a plasma energy and the removal step using a thermal energy has been developed, and an attempt for changing a high temperature and a low temperature in stages is to be made in various ways. However, the known art does not disclose an ALE technology or a dry cleaning technology to satisfy high efficiency and productivity at the same time.

The present invention is intended to solve the problem of the prior art and has the following purpose.

### Purpose of the Invention

The object of the present invention is to provide with a shallow etching process chamber to perform a low temperature modification step using a plasma energy in a way to satisfy high efficiency and high productivity simultaneously.

### SUMMARY OF THE INVENTION

In one embodiment of the present invention, a shallow process chamber comprises a susceptor disposed within a chamber volume; a lifting ring formed at the susceptor; and a moving means for moving the lift ring up and down, wherein a wafer W can move up and down above an electrostatic chuck by moving the lift ring up and down.

In other embodiment of the present invention, the chamber further comprises an internal shower head and an external shower head, and a shower head heater is disposed at the internal shower head.

In another embodiment of the present invention, the chamber further comprises a baffle disposed between the internal shower head and the external shower head.

In still another embodiment of the present invention, the lift ring 18 moves up and contacts the baffle.

In still another embodiment of the present invention, a process volume is formed between the internal shallow head and the wafer as the lift ring moves up.

In still another embodiment of the present invention, the chamber further comprises a ring heat disposed within the lift ring.

In still another embodiment of the present invention, the moving means comprises a pair of linear gears and a pair of lift shafts capable of moving along the pair of linear gears.

In still another embodiment of the present invention, the chamber further comprises an internal shower head and a moving gas wall capable of moving up and down in order to surround the internal shower head.

In still another embodiment of the present invention, a flow path is formed at the baffle.

In still another embodiment of the present invention, the rift ling contacts a bottom surface of the baffle, a portion of the bottom surface of the baffle or the bottom surface and an inner surface of the baffle.

### BRIEF DESCRIPTION OF THE DRAWINGS

FIG. 1 shows an embodiment of a shallow etching process chamber according to the present invention.

FIG. 2 shows an embodiment of an operating structure of the process chamber according to the present invention.

FIG. 3 shows an embodiment of a mutual positional relationship between the baffle and the lift ring in the process chamber according to the present invention.

FIG. 4 shows other embodiment of a shallow etching process chamber according to the present invention.

FIG. 5 shows an embodiment of an ALE (Atomic Layer Etching) process performed in the etching process chamber.

### DETAILED DESCRIPTION OF EXEMPLARY EMBODIMENTS

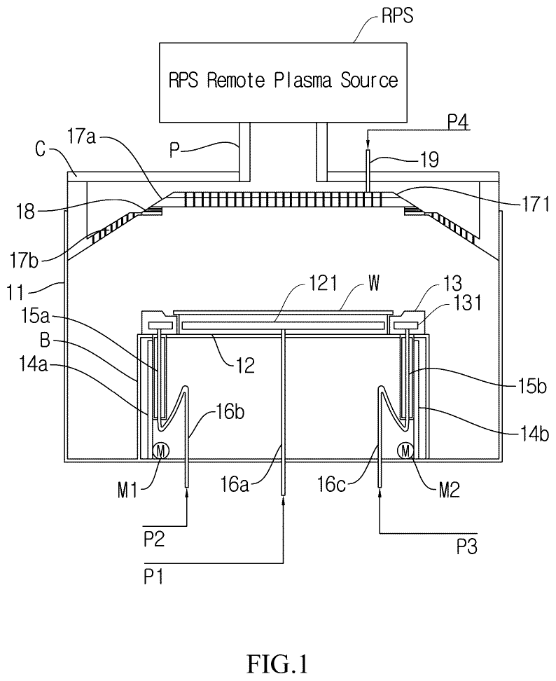

FIG. 1 shows an embodiment of a shallow etching process chamber according to the present invention.

Referring to FIG. 1, A shallow process chamber comprises a susceptor disposed within a chamber volume 11; a lifting ring 13 formed at both sides of the susceptor; and a moving means for moving the lift ring 13 up and down, wherein a wafer W can move up and down above an electrostatic chuck 12 by moving the lift ring 13 up and down. The chamber volume 11 may be separated from an outside by a bottom surface and a surrounding wall, and a cover C may be coupled at an upper part of the chamber volume 11.

The chamber volume 11 may be made as a vacuum condition, and a plasma is generated within the chamber volume, or a generated plasma may be introduced within the chamber volume 11. The chamber volume 11 may have various structures in which a semiconductor process or an etching process can be performed. A base block B may be formed within the chamber volume 11, and the susceptor is disposed at the upper part of the base block B for fixing the wafer W. The susceptor may become various means to fix the wafer W, and the susceptor may comprise a heater or a coolant flow path. For example, the susceptor may comprises an electrostatic chuck 12, and the electrostatic chuck 12 is demonstrated as an example for explanation, but the susceptor is not limited thereto. The electrostatic chuck 12 may be disposed on the base block B, and the heater 121 may be disposed within the electrostatic chuck 12, and the wafer W to be etched may be fixed on the upper surface of the electrostatic chuck 12.

And a lift ring 13 may be disposed on the circumference surface of the electrostatic chuck 12 for fixing the wafer W fixed on the upper surface of the electrostatic chuck 12 to maintain a plasma density uniformly and to prevent the wafer W from being contaminated. The lift ring 13 may have the same function as that of an edge ring or the function identical to that of an edge ring, for example, the lift ring 13 may be an edge ring. The heater 131 may be installed within the lift ring 13 for regulating a temperature of the lift ring 13. The lift ring 13 may support the peripheral portion of the wafer W, and the opposite both sides of lift ring 13 may move up and down by a moving means. As the lift ring 13 supporting the wafer W moves upward, the wafer W moves in an upward direction together with the lift ring 13. Hence, the lift ring 13 may have a function to move the wafer W up and down. The moving means comprises a pair of linear gears 14a, 14b and a pair of lift shafts 15a, 15b capable of moving along the pair of linear gears 14a, 14b. The first and second linear gear 14a, 14b may extend from a bottom surface of the chamber volume 11 to an upper part of the chamber volume 11 in a vertical direction, and engaging teeth may be formed at each side of each linear gear 14a, 14b along the extending direction of the first and second linear gear 14a, 14b. In this way, each lift shaft 15a, 15b may be coupled to each linear gear 14a, 14b in a manner to move up and down. The upper ends of lift shafts 15a, 15b may be coupled to the lower parts of the lift ring 13 facing each other, and as each lift shaft 15a, 15 moves up and down along each linear gear 14a, 14b by a first and second motor M1, M2, the lift ring 13 moves up and down. For example, the lift shafts 15a, 15b may comprise pinion gears engaged to the linear gears 14a, 14b.

The vertical movement of the lift shafts 15a, 15b relative to the linear gears 14a, 14b may be performed in various ways, but not limited to. A power for controlling the temperature may be supplied to the heater 121 disposed at the electrostatic chuck 12 or the heater 131 disposed within the lift ring 13, and the power may be supplied to the heater 121 of the electrostatic heater 121 and the heater 131 of the lift ring 131 through a first, second and third cable 16a, 16b, 16c from a first, second and third power supplying means P1, P1, P3 for controlling the temperature of the electrostatic chuck 12 or the lift ring 13. For example, the temperature of the electrostatic chuck 12 may be regulated in a range of 20 to 80° C., and the temperature of the lift ring 13 may be regulated in a range of 150 to 300° C. The power may be supplied both opposite sides of the heater 131 disposed within the lift ring 13 for controlling the temperature of the lift ring 13. The heater 131 may be installed within the lift ring 13 in various ways, and for example, a circular heater 131 may be installed within the lift ring 13 along the entire length of the lift ring 131, or the heater 131 may be disposed at both sides of the lift ring 13, but not limited to. A cover C may be coupled to the upper portion of the chamber volume 11, and an inflowing path P for introducing the plasma from a remote plasma source RPS to the inside of the chamber volume 11 may be formed at a center part of the cover C.

And also, the internal shower head 17a may be placed at the lower part of the cover C, and the external shower head 17b may be placed outside the peripheral part of the internal shower head 17a. The internal shower head 17a or the external shower head 17b may be made from an aluminum material, but not limited to. The internal shower head 17a may have a plane plate shape such as a circular plate or a polygonal plate, and a plurality of penetrating holes may be formed at the whole internal shower head from top to bottom for the inflow of the plasma or a gas. And also, a heater 171 may be installed within the internal shower head 17a to make the temperature of the internal shower head 17a be in a range of 300 to 400° C. by supplying the power through the cable 19 connected to the power supplying means P4. The edge of the internal shower head 17a may be inclined in a downward direction, and the external shower head 17b may be disposed at the outside of the internal shower head 17a. The external shower head 17b may have an inclined shape in the outer direction, and the inclination shape may become connected to the inclined edge of the internal shower head 17a. A plurality of penetrating holes such as the penetrating holes formed at the internal shower head 17a may be formed uniformly at the external shower head 17b for introducing the plasma or the gas into the chamber volume 11.

A baffle 18 may be disposed between the internal shower head 17a and the external shower head 17b, and at least one slit or penetrating hole may be formed at the baffle 18 in a horizontal direction or a direction similar to the horizontal direction. The baffle 18 may be made from a quartz or the like, but not limited to. The baffle 18 may comprise an inclined outer surface, and the inclined outer surface may be connected to the inclined edge surface of the internal shower head 17a and the inclined surface of the external shower head 17b. The baffle 18 can be made as various structures to prevent a heat transfer between the internal shower head 17a and the external shower head 17b and prevent an attack of some radical, but not limited to. An etching process may be performed in the above discussed process chamber and the process will be discussed below in detail.

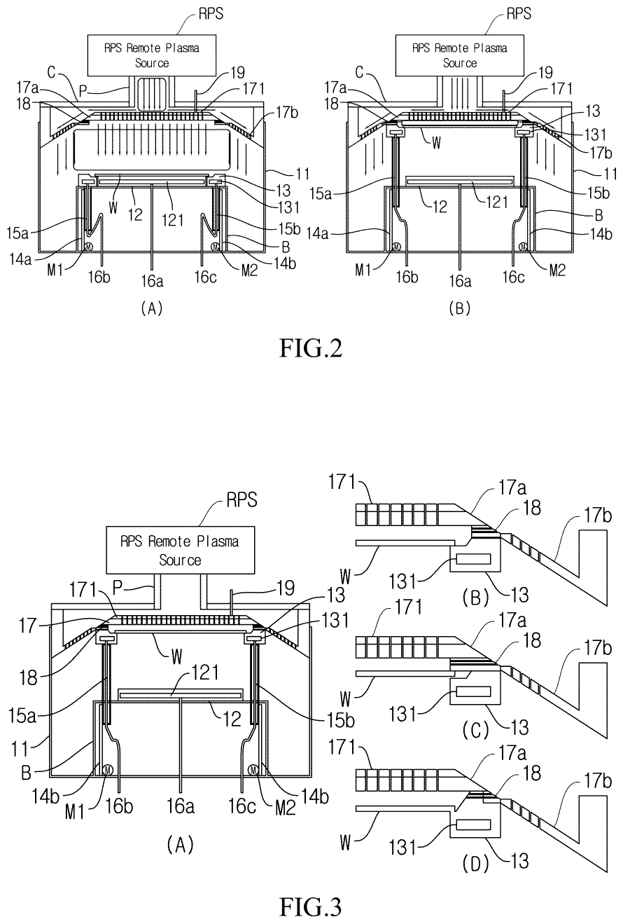

FIG. 2 shows an embodiment of an operating structure of the process chamber according to the present invention.

Referring to FIG. 2, a modification step belonging to one of the etching process may be performed with the wafer W positioned on the electrostatic chuck, as shown in (A), and a removal step may be performed with the wafer W moved upward as showed in (B). A plasma generated by the remote plasma source RPS may inflow within the chamber volume 11 through the inflow path P, and an ion or a radical for the modification step may be made by the introduced plasma and NH3, NF3 or Ar existing within the chamber volume 11. The wafer W may be fixed on the upper part of the electrostatic chuck 12. In particular, wafer W may be fixed on the susceptor, and the susceptor can be made of an aluminum and the susceptor may comprise a heater or a cooler. The internal shower head 17a formed at the upper part of the electrostatic chuck 12 may have a function to enable the generated ion and the radical to flow uniformly toward the upper surface of the wafer W fixed on the susceptor. The temperature of the inner shower head 17a may be maintained in range of 300 to 400° C. by the power supplied to the heater 171 from the power supplying means through the cable 19. The external shower head 17b may have a function control a process uniformity between the side surface of the internal shower head 17a and the peripheral wall.

A gas may flow in the side direction of the internal shower head 17a or the external shower head through the slits or the penetrating holes formed at the baffle 18 along the horizontal direction. The baffle 18 may have a function to block the heat from being delivered from the internal shower head 17a to the external shower head 17b, and the baffle 18 may be made of a quartz or the like for preventing an attack of the radical. And also, the internal shower head 17a, the external shower head 17b, the peripheral wall of the chamber volume or the cover C may be made of an aluminum or the like. In addition, the susceptor may be made of an aluminum or the like, and the temperature of the susceptor may be maintained in range of 20 to 80° C. using the power supplied from the power supplying means to the heater 121 through the cable. The lift ring 13 may be made of an aluminum or a quartz with a ring shape, and the heater 131 may be disposed within the lift ring 13, as described above. And a power may be supplied to the heater 131 through the cable 16b, 16c from the power supplying means to maintain a temperature of the lift ring 13 in a range of 150 to 300° C.

In this condition, the plasma may be supplied from the remote plasma source RPS with a 500 to 3,000 W power to perform the modification step in an existence of NH3, NF3 and Ar. And the inner part of the chamber volume 11 may have the following temperature condition; the area of the internal shower head 17a: about 400° C., the area of the external shower head 17b: about 150° C., an area adjacent to the wafer W: about 200° C., an area below the wafer W: about 100° C., and the area of the susceptor: about 50° C. If the modification step is completed in such process conditions, the lift ring 13 moves to the upward part of the chamber volume 11 by a moving means including a pair of linear gear 14a, 14b, a pair of lift shafts 15a, 15b and a pair of motors M1, M2. The contacting length of the lift ring 13 and the wafer W may be about 2 mm, and the lift ring 13 may be contact the wafer W along a diameter direction from the circumference.

The lift ring 13 may move upward to contact the baffle 18. Thereby, a removal process volume with a narrow size for performing the removal process may be made by the internal shower head 17a, the baffle 18, the lift ring 13 and the wafer W. In this state, the inflow of the plasma from the remote plasma source RPS may be blocked, and a thin film formed at the wafer W may be removed by an Ar existing within the removal process volume, as shown in FIG. 2 (B). The Ar required for the removal process in the removal process volume may inflow within the removal process volume through the penetrating holes formed at the internal shower head 17a. Then, after the removal step is completed, the remaining Ar may be discharged through the penetrating holes or slits formed at the baffle 18.

The high temperature of the internal shower head 17a, a distance between the wafer W and the internal shower head 17a or the temperature of the wafer W may be regulated properly. And also, a distance between the internal shower head 17a and the wafer W, a gas flow capacity of the baffle 18 and a gas flow amount may be controlled in the removal process volume, thereby an inner pressure of the removal process volume may be controlled. The internal shower head 17a or the lift ring 13 may have various structures required for forming the removal process volume, controlling the temperature or the pressure. For example, the internal shower head 17a or the lift ring 13 may have various structures for limiting a gas flow and controlling a gas flow and a gas pressure. And also, as discussed below, a moving gas wall may be disposed above the internal shower head 17a in order to enhance a process uniformity by controlling the gas flow amount and the pressure within the removal process volume. The internal shower head 17a, the lift ring 13 or the baffle 18 may have various structures capable of controlling the temperature and the pressure within the removal process volume, the volume size or the gas flow, but not limited to.

FIG. 3 shows an embodiment of a mutual positional relationship between the baffle and the lift ring in the process chamber according to the present invention.

Referring to FIG. 3, the lift ring 13 contacts the bottom surface of the baffle 18, a portion of the bottom surface of the baffle 18, or the bottom surface and the inner surface of the baffle 18. The linear gears 14a, 14b and the lift shafts 15a, 15b may be operated by the motors M1, M2, and the lift ring 13 may move upward to contact baffle 18.

Referring to FIG. 3 (B), the lift ring 13 may have a ring shape as a whole, the inner part of the lift ring 13 may become a plane shape, the middle part of the lift ring 13 may become an inclined shape extending from the plane shape outward and upward and the outer part of lift ring 13 may become a flat shape connected to the inclined shape. And also, the upper surface of the baffle 18 may extend as a plane shape, and then the baffle 18 may extend as an inclined shape in the downward direction. And the bottom surface of the baffle 18 may have a plane shape. In this structure of the lift ring 13 and the baffle 18, the outer plane of the lift ring 13 may contact the bottom surface of the baffle 18, thereby the side surface of the removal process volume may be sealed and the gas such as the Ar may flow through the penetrating holes formed at the baffle 18.

Referring to FIG. 3 (C), the baffle 18 may extend to a relatively large length in an inner direction of the internal shower head 17a, and the outer surface of the lift ring 13 may contact a portion of the bottom surface of the baffle 18. And a gap may be formed between the inner surface of the lift ring 13 and a not-contacting surface of the baffle 18.

Referring to FIG. 3 (D), the lift ring 13 may comprise an inner plane, an inclined plane extending outwardly, a middle plane and a step plane formed below the middle plane. The edge part of the wafer W may contact the inner plane, for example, the length of the inner plane may be 2.0 to 3.0 mm. The baffle 18 may comprise an inner vertical plane and a bottom plane, and a vertical boundary surface formed by the middle plane and the step plane contact the vertical plane. And the bottom plane of the baffle 18 may contact the step plane. In such a contacting structure, guiding holes connected to the penetrating holes of the baffle 18 may be formed at the lift ring 13. In this way, the lift ring 13 or the baffle 18 may have various structures to contact each other and to seal the side surface of the removal process volume, but not limited to.

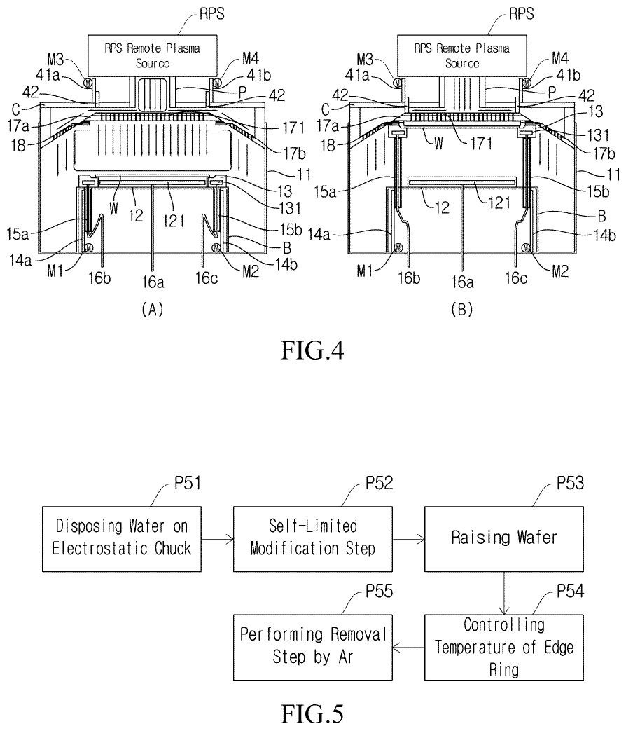

FIG. 4 shows other embodiment of a shallow etching process chamber according to the present invention.

Referring to FIG. 4, the etching process chamber further comprises a moving gas wall 42 capable of moving up and down and capable of enclosing the internal shower head 17a. As shown in FIG. 4 (A), the moving gas wall 42 may be located above the cover C in the modification step. The moving gas wall 42 may have a hollow cylindrical shape or a hollow polyhedral shape. A pair of gear units 41a, 41b for transferring the moving gas wall 42 may be placed at opposite positions, and in the removal process the moving gas wall 42 may move downward along the pair of gear units 41a, 41b by an operation of the motor M3 as shown FIG. 4(B). Therefore, the moving gas wall 42 may be located at the position to surround the internal shower head 17a. Thereby, the gas inflow into the removal process volume through the penetrating holes formed at the internal shower head 17a is limited. The moving gas wall 42 may have a shape suitable for surrounding the internal shower head 17a, and the moving gas wall 42 may move in various ways, but not limited to.

FIG. 5 shows an embodiment of an ALE (Atomic Layer Etching) process performed in the etching process chamber.

Referring to FIG. 5, a method for performing an ALE process in the etching process chamber comprises fixing the wafer on the susceptor P51; controlling the temperature of the etching process chamber and performing the self-limited modification by introducing the plasma within the chamber P62; forming the removal process volume at the upper part of the chamber by raising the edge ring for moving the wafer upward after completing the self-modification process P53; controlling the temperature of the edge ring, the pressure of the removal process volume and the condition of the gas flow P54; and performing the removal process by the Ar gas P55.

An ion or a radical for the self-modification process may be created by the plasma generated from the remote plasma source, and the internal shower head may be disposed in order that the created ion or radical flows uniformly toward the upper surface of the wafer. The temperature of the internal shower head may be in a range of 300 to 400° C., and the external shower head for controlling the process uniformity may be disposed between the side of the internal shower head and the wall of the chamber. The baffle may be disposed between the internal shower head and the external shower head, thereby the gas can flow along the side surface formed by the internal shower head and the external shower head. The baffle may be made of a quartz, for example, in order to block a heat from being transferred and to prevent an attack by the radical. And also, the internal shower head, the external shower head and the wall of chamber may be made of an aluminum material. And also, the susceptor for fixing the wafer may be made of the aluminum and the susceptor may comprise a heater or a coolant path for the flow of a cooling water. The edge ring supporting the edge part of the wafer may be made of the aluminum or the quartz material, and a heater may be disposed within the edge ring. The temperature of the edge ring may be maintained in a range of 150˜300° C. using the heater.

The plasma may inflow within the chamber under this condition, and the modification step may be performed P52. The edge ring may comprise a moving means for moving the edge ring up and down, and the edge ring can move to the internal shower head by the moving means, and the wafer may move upward by the edge ring P53. In the modification step, the wafer fixed on the susceptor may have a temperature of 20˜80° C., and the self-limited modification step may be performed by the ions and radicals formed by the plasma.

On the contrary, in the removal step performed within the removal process volume formed by raising the wafer, the wafer may be raised upward by the edge ring with a high temperature of 150˜300° C., and the edge ring may move upward till the edge ring contacts the baffle. Thereby the wafer may be located adjacent to the internal shower head maintained as a temperature of 300 to 400° C. The removal process chamber may be formed by the internal shower head with a high temperature, the wafer, the baffle and the edge ring, and the temperature, the pressure or the gas flow condition of the removal process volume may be controlled P54. The removal process volume may have a narrow size, and the gas such as Ar for performing the removal step may be filled within the removal process volume through the penetrating holes formed at the internal shower head. And also, such gas may be discharged to the outside through the penetrating holes or the slits formed at the baffle.

The temperature of the wafer may be controlled in the removal step by regulating the set temperature of the internal shower head with the high temperature and the distance between the wafer and the internal shower head, and the removal step for removing the thin film formed in the modification may be performed P55. The pressure of the removal process volume may be controlled by the distance between the internal shower head and the wafer, the gas flow capacity of the baffle or the gas flow amount. The size, the gas flow amount or the pressure of the removal process volume may be controlled by the various baffle shapes or edge ring shapes, but not limited to. Alternatively, the moving gas wall may be formed above the internal shower head for enhancing the uniformity. Various components for forming the removal process condition in the removal process volume may be added, but not limited to.

What is claimed is:

1. A shallow process chamber comprising:
a susceptor disposed within a chamber volume;
a lifting ring formed at the susceptor; and
a moving means for moving the lift ring up and down,
wherein a wafer moves up and down above an electrostatic chuck by moving the lift ring up and down.

2. The shallow etching process chamber according to claim 1, wherein the chamber further comprises an internal shower head and an external shower head, and a shower head heater is disposed at the internal shower head.

3. The shallow etching process chamber according to claim 2, wherein the chamber further comprises a baffle disposed between the internal shower head and the external shower head.

4. The shallow etching process chamber according to claim 3, wherein the lift ring moves up and contacts the baffle.

5. The shallow etching process chamber according to claim 1, wherein a process volume is formed between the internal shallow head and the wafer as the lift ring moves up.

6. The shallow etching process chamber according to claim 1, wherein the chamber further comprises a ring heat disposed within the lift ring.

7. The shallow etching process chamber according to claim 1, wherein the moving means comprises a pair of linear gears and a pair of lift shafts capable of moving along the pair of linear gears.

8. The shallow etching process chamber according to claim 1, wherein the chamber further comprises an internal shower head and a moving gas wall capable of moving up and down in order to surround the internal shower head.

9. The shallowing etching process chamber according to claim 3, wherein a flow path is formed at the baffle.

10. The shallow etching process chamber according to claim 3, wherein the rift ling contacts a bottom surface of the baffle, a portion of the bottom surface of the baffle or the bottom surface and an inner surface of the baffle.
